(19) United States
(12) Patent Application Publication
(10) Pub. No.: US 2024/0332142 A1
(43) Pub. Date: Oct. 3, 2024

(54) POWER SEMICONDUCTOR MODULE WITH ADAPTABLE POWER CONTACTS AND METHOD FOR FABRICATING THE SAME

(71) Applicant: Infineon Technologies AG, Neubiberg (DE)

(72) Inventors: Michael Fügl, Neumarkt (DE); Thorsten Scharf, Lappersdorf (DE)

(21) Appl. No.: 18/609,586

(22) Filed: Mar. 19, 2024

(30) Foreign Application Priority Data
Mar. 30, 2023 (DE) 102023202953.7

(51) Int. Cl. H01L 23/495; H01L 21/56; H01L 21/60; H01L 23/31

(52) U.S. Cl. CPC H01L 23/49555; H01L 21/56; H01L 21/60; H01L 23/3107; H01L 23/49575

(57) ABSTRACT

A power semiconductor module includes an encapsulation encapsulating power semiconductor dies. The encapsulation includes lateral sides connecting first and second opposite sides. First and second power contacts are electrically coupled to the power semiconductor dies. An isolation part arranged between the power contacts electrically isolates the contacts from one another. The power contacts have a flat shape and are stacked such that their broadest surfaces at least partially overlap. A first portion of the power contacts is parallel to a first plane. A second portion is twisted and/or bent with respect to the first portion such that the second portion is parallel to a second plane arranged at a non-zero angle with respect to the first plane. At least a part of the first portion is encapsulated by the encapsulation. At least a part of the second portion is exposed from the encapsulation at one of the lateral sides.

### TECHNICAL FIELD

This disclosure relates in general to a power semiconductor module with adaptable power contacts as well as to a method for fabricating such a power semiconductor module.

### BACKGROUND

Power semiconductor modules may be used in a variety of applications. For example, a power semiconductor module may be part of a traction inverter application for the automotive sector. Different inverters may have different geometries and it may be desirable for a power semiconductor module to be adaptable to such differences. In particular, the external contacts, e.g. direct current (DC) contacts, of the module may be required to fit different inverter geometries. Furthermore, it may be beneficial if all steps of mounting the power semiconductor module into the inverter can be performed from a single direction (e.g. solely from above or solely from below) in order to reduce complexity and costs of the mounting process. Improved power semiconductor modules and improved methods for fabricating power semiconductor modules may help in solving these and other problems.

### SUMMARY

Various aspects pertain to a power semiconductor module, comprising: an encapsulation encapsulating a plurality of power semiconductor dies, the encapsulation comprising a first side, an opposite second side and lateral sides connecting the first and second sides, a first and a second power contact electrically coupled to the power semiconductor dies, and an isolation part arranged between the first and second power contacts and electrically isolating the power contacts from one another, wherein the power contacts have a flat shape, wherein the power contacts are stacked such that broadest surfaces of the power contacts at least partially overlap, wherein a first portion of the power contacts is parallel to a first plane and a second portion of the power contacts is twisted and/or bent with respect to the first portion such that the second portion is parallel to a second plane, the second plane being arranged at a non-zero angle with respect to the first plane, and wherein at least a part of the first portion is encapsulated by the encapsulation and at least a part of the second portion is exposed from the encapsulation at one of the lateral sides.

Various aspects pertain to a power semiconductor module, comprising: an encapsulation encapsulating a plurality of power semiconductor dies, the encapsulation comprising a first side, an opposite second side and lateral sides connecting the first and second sides, a first and a second power contact electrically coupled to the power semiconductor dies, and an isolation part arranged between the first and second power contacts and electrically isolating the power contacts from one another, wherein a part of the power contacts is exposed from the encapsulation at one of the lateral sides, wherein the first and second power contacts have different lengths such that a distal end of the second power contact is at a greater distance from the respective lateral side than a distal end of the first power contact, wherein the power contacts have a flat shape, wherein the power contacts are stacked such that broadest surfaces of the power contacts at least partially overlap between the respective lateral side and the distal end of the first power contact, and wherein viewed from above the broadest surfaces, the power contacts have a T-shape or an L-shape.

Various aspects pertain to a method for fabricating a power semiconductor module, the method comprising: encapsulating a plurality of power semiconductor dies with an encapsulation, the encapsulation comprising a first side, an opposite second side and lateral sides connecting the first and second sides, electrically coupling a first and a second power contact to the power semiconductor dies, and arranging an isolation part between the first and second power contacts, the isolation part electrically isolating the power contacts from one another, wherein the power contacts have a flat shape, wherein the power contacts are stacked such that broadest surfaces of the power contacts at least partially overlap, wherein a first portion of the power contacts is parallel to a first plane and a second portion of the power contacts is twisted and/or bent with respect to the first portion such that the second portion is parallel to a second plane, the second plane being arranged at a non-zero angle with respect to the first plane, and wherein at least a part of the first portion is encapsulated by the encapsulation and at least a part of the second portion is exposed from the encapsulation at one of the lateral sides.

Various aspects pertain to a method for fabricating a power semiconductor module, the method comprising: encapsulating a plurality of power semiconductor dies with an encapsulation, the encapsulation comprising a first side, an opposite second side and lateral sides connecting the first and second sides, electrically coupling a first and a second power contact to the power semiconductor dies, and arranging an isolation part between the first and second power contacts, the isolation part electrically isolating the power contacts from one another, wherein a part of the power contacts is exposed from the encapsulation at one of the lateral sides, wherein the first and second power contacts have different lengths such that a distal end of the second power contact is at a greater distance from the respective lateral side than a distal end of the first power contact, wherein the power contacts have a flat shape, wherein the power contacts are stacked such that broadest surfaces of the power contacts at least partially overlap between the respective lateral side and the distal end of the first power contact, and wherein viewed from above the broadest surfaces, the power contacts have a T-shape or an L-shape.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIGS. 1A to 1D show a power semiconductor module, wherein power contacts have a first portion and a second portion, wherein the second portion is twisted with respect to the first portion.

FIG. 2 shows a further power semiconductor module, wherein the second portion of the power contacts is twisted with respect to the first portion.

FIG. 3 shows a perspective view of power contacts for a power semiconductor module, wherein the second portion of the power contacts is twisted with respect to the first portion.

FIG. 4 shows a further power semiconductor module, wherein the power contacts have a T-shape.

FIG. 5 shows a further power semiconductor module, wherein a third portion of the power contacts is bent with respect to the first and second portions.

FIG. 6 is a flow chart of a method for fabricating a power semiconductor module.

FIG. 7 is a flow chart of a further method for fabricating a power semiconductor module.

### DETAILED DESCRIPTION

In the following detailed description, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a power semiconductor module described below may use various types of semiconductor chips or circuits incorporated in the semiconductor chips, among them AC/DC or DC/DC converter circuits, power MOS transistors, power Schottky diodes, JFETs (Junction Gate Field Effect Transistors), power bipolar transistors, power integrated circuits, etc. The examples may also use semiconductor chips comprising MOS transistor structures or vertical transistor structures like, for example, IGBT (Insulated Gate Bipolar Transistor) structures or, in general, transistor structures in which at least one electrical contact pad is arranged on a first main face of the semiconductor chip and at least one other electrical contact pad is arranged on a second main face of the semiconductor chip, opposite to the first main face of the semiconductor chip. The semiconductor chips may comprise or consist of any suitable semiconductor material, for example Si, SiC or GaN.

An efficient power semiconductor module and an efficient method for fabricating a power semiconductor module may for example reduce material consumption, ohmic losses, chemical waste, etc. and may thus enable energy and/or resource savings. Improved power semiconductor modules and improved methods for fabricating a power semiconductor module, as specified in this description, may thus at least indirectly contribute to green technology solutions, i.e. climate-friendly solutions providing a mitigation of energy and/or resource use.

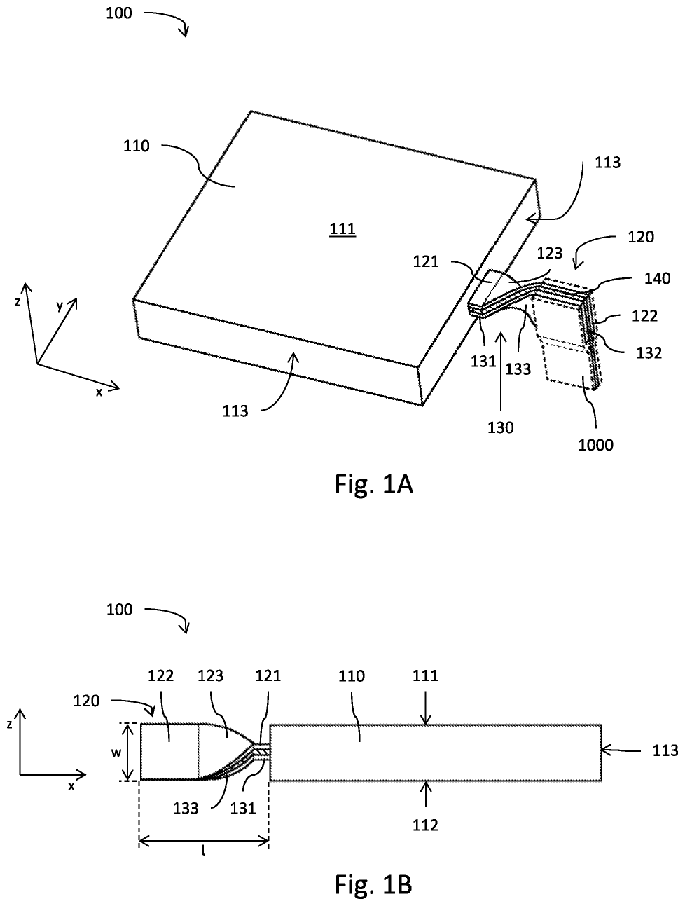

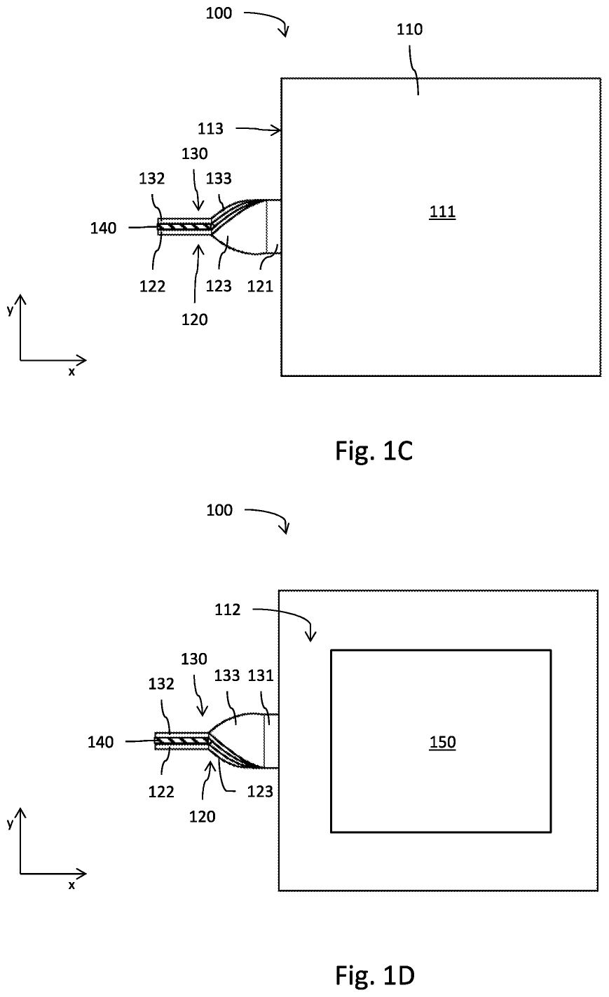

FIGS. 1A to 1D show a power semiconductor module 100 comprising an encapsulation 110, a first power contact 120, a second power contact 130 and an isolation part 140. FIG. 1A shows a perspective view, FIG. 1B shows a side view, FIG. 1C shows a top view and FIG. 1D shows a bottom view.

The power semiconductor module 100 may be configured to operate with a high voltage and/or a high electrical current. The power semiconductor module 100 may for example comprise an inverter circuit, a converter circuit, a half bridge circuit, a full bridge circuit, a B6 bridge circuit, etc. The power semiconductor module 100 may for example be configured for use in automotive applications, e.g. as (part of) an inverter.

The encapsulation 110 encapsulates a plurality of power semiconductor dies (not shown in FIGS. 1A-1D). The encapsulation comprises a first side 111, an opposite second side 112 and lateral sides 113 connecting the first and second sides 111, 112. The encapsulation 110 may have any suitable shape and any suitable dimensions. In the example shown in FIGS. 1A-1D, the encapsulation 110 has a quadratic shape as viewed from above the first side 111. However, the encapsulation 110 may also for example have a rectangular shape. A height of the encapsulation 110 (measured along the z-axis) may be smaller than a length and/or a width of the encapsulation 110 (measured along the x-axis and the y-axis, respectively).

According to an example, the encapsulation 110 has a length and/or a width in the range of about 2 cm to about 40 cm. The lower limit of this range may also be about 4 cm, 6 cm, 8 cm, or 10 cm and the upper limit may also be about 30 cm, 20 cm, or 15 cm. According to an example, the encapsulation 110 has a height in the range of 5 mm to 5 cm. The lower limit of this range may also be about 8 mm, 10 mm, 15 mm, or 17 mm and the upper limit may also be about 4 cm, 3 cm, or 2 cm.

The encapsulation 110 may for example comprise or consist of a frame and/or a molded body. A frame may for example comprise or consist of plastic and/or a suitable metal, e.g. Al. An interior volume of such a frame may be at least partially filled with a suitable potting material. A molded body may comprise or consist of any suitable mold material, in particular a polymer. A molded body may also comprise inorganic filler particles configured to reduce the thermal resistance of the molded body.

As shown in FIG. 1D, a thermal contact part 150 may be exposed from the second side 112 of the encapsulation 110. The thermal contact part 150 may for example comprise or consist of a metal plate, e.g. a leadframe part, a substrate of the type direct copper bond (DCB), direct aluminum bond (DAB) or active metal brazed (AMB), or a lamination layer. The thermal contact part 150 may be (part of) a substrate, wherein a power semiconductor die of the power semiconductor module 100 is arranged over the substrate, or the thermal contact part 150 may be mechanically and thermally coupled to such a substrate. The thermal contact part 150 may be configured to be coupled to a heatsink.

In the example shown in FIG. 1D, the thermal contact part 150 constitutes only a part of the surface area of the second side of the power semiconductor module 100, e.g. 70% or more. According to another example, the thermal contact part 150 may constitute the whole or almost the whole surface area of the second side. According to yet another example, the power semiconductor module 100 does not comprise the thermal contact part 150.

The first and a second power contacts 120, 130 are electrically coupled to the power semiconductor dies. For example, the power semiconductor dies may be arranged on and electrically coupled to one or more substrates and the first and/or the second power contact 120, 130 may be coupled to the power semiconductor dies via the substrate(s). Additionally or alternatively, electrical connectors like for example bond wires, ribbons or contact clips may be used to couple the first and/or the second power contact 120, 130 to the power semiconductor dies. The power contacts 120, 130 may be coupled to power terminals of the power semiconductor dies, e.g. to a drain, source, emitter or collector terminal.

The power contacts 120, 130 may be DC-contacts configured to carry a direct current or to have a direct voltage applied or the power contacts 120, 130 may be AC-contacts configured to carry an alternating current. The power contacts 120, 130 may comprise or consist of any suitable metal or metal alloy and may for example comprise or consist of Al, Ag or Cu. According to an example, the power contacts 120, 130 are at least partially covered with a plating, e.g. a Ni-plating (for example, at least a part of the power contacts 120, 130 that is exposed from the encapsulation 110 may be plated). According to an example, the power contacts 120, 130 are leadframe parts.

The power contacts 120, 130 have a flat shape. This may in particular mean that a thickness of the power contacts 120, 130 is smaller than a width and length of the power contacts 120, 130. For example, the power contacts 120, 130 may have a thickness in the range of about 0.1 mm to about 10 mm. The lower limit of this range may also be about 0.3 mm, 0.5 mm, 0.8 mm, 1 mm, or 2 mm and the upper limit may also be about 5 mm, 4 mm, or 3 mm. The part of the power contacts 120, 130 that is external to the encapsulation 110 may for example have a length 1 (see FIG. 1B) in the range of about 5 mm to about 10 cm. The lower limit of this range may also be about 1cmm, 1.5 cm, 2 cm, or 3 cm and the upper limit may also be about 8 cm, 6 cm, or 4 cm. The power contacts 120, 130 may for example have a width w in the range of about 2 mm to about 20 cm. The lower limit of this range may also be about 5 mm, 10 mm, or 15 mm and the upper limit may also be about 15 cm, 10 cm, 6 cm, 4 cm, 3 cm, or 2 cm.

The power contacts 120, 130 are stacked such that broadest surfaces of the power contacts 120, 130 at least partially overlap. In this context, “overlap” may mean that the circumference of the first contact 120 and the circumference of the second contact 130 are in vertical alignment. In the example shown in FIGS. 1A-1D, the broadest surfaces of the power contacts 120, 130 completely overlap (at least for those parts of the power contacts 120, 130 that are external to the encapsulation 110. Such overlapping broadest surfaces may for example help in reducing stray inductance in the power semiconductor module 100.

A first portion 121 of the first power contact 120 and a first portion 131 of the second power contact 130 are parallel to a first plane (the xy-plane in FIGS. 1A-1D) and a second portion 122 of the first power contact 120 and a second portion 132 of the second power contact 130 are twisted with respect to the first portions 121, 131 such that the second portions 122, 132 are parallel to a second plane (the xz-plane in FIGS. 1A-1D). Furthermore, the second plane is arranged at a non-zero angle with respect to the first plane. It is not necessary that the second portions 122, 132 are twisted exactly in the way shown in FIGS. 1A-1D. In general, it is also possible that the power contacts 120, 130 comprise any suitable kind of bend (or several bends) in order to have the second portions 122, 132 arranged in the second plane. For example, the power contacts 120, 130 may comprise one or more bends going upwards or downwards and/or to the left or to the right and/or a twist in order to have the second portions 122, 132 arranged in the second plane.

In the example shown in FIGS. 1A-1D, the non-zero angle is an angle of 90°. However, the non-zero angle may be any suitable angle and may also for example be about 10°, 20°, 30°, 40°, 50°, 60°, 70°, or 80°. The non-zero angle may also be within a range of ±5° of any of the aforementioned values.

As shown in FIGS. 1A-1D, the power contacts 120, 130 may each comprise a twist portion 123, 133 arranged between the first portions 121, 131 and the respective second portions 122, 132. The power contacts 120, 130 may twist from the first plane (e.g. the xy-plane) into the second plane (e.g. the xz-plane) along the twist portion. For example, the power contacts 120, 130 may be twisted in a helical manner along the twist portions 123, 133. Additionally or alternatively, the power contacts 120, 130 may comprise one or more bend portions arranged between the first portions 121, 131 and the second portions 122, 132, wherein the power contacts 120, 130 bend from the first plane into the second plane along the one or more bend portions.

According to the example shown in FIGS. 1A-1D, the twist portions 123, 133 are exposed from the encapsulation 110. It is however also possible that the twist portions 123, 133 are encapsulated by the encapsulation 110 and/or by a further cover that is different from the encapsulation 110.

At least a part of the first portions 121, 131 of the power contacts 120, 130 is encapsulated by the encapsulation 110. In other words, a part of the first portions 121, 131 extends into the interior of the power semiconductor module 100 and is electrically coupled to the power semiconductor dies. At least a part of the second portions 122, 132 of the power contacts 120, 130 is exposed from the encapsulation 110 at one of the lateral sides 110. In the example shown in FIGS. 1A-1D, the second portions 122, 132 are completely exposed from the encapsulation 110. In the example shown in FIGS. 1A-1D, the first and second power contacts 120, 130 have essentially the same shape and the same dimensions. It is however also possible that the power contacts 120, 130 have a different shape and/or different dimensions, for example a different width.

In the example shown in FIG. 1A, the power contacts 120, 130 are coupled to a bus bar 1000 which is not part of the power semiconductor module 100 (the bus bar 1000 is therefore depicted with dashed lines). Such a coupling may for example be done by welding, in particular laser welding from a direction above the power semiconductor module 100. In FIGS. 1B-1D the bus bar 1000 is omitted and only the power semiconductor module 100 is shown.

The isolation part 140 is arranged between the first and second power contacts 120, 130 and electrically isolates the power contacts 120, 130 from one another. According to the example shown in FIGS. 1A-1D, a circumference of the isolation part 140 has about the same thickness as the power contacts 120, 130. However, the isolation part 140 may have any suitable thickness and may for example be thicker or thinner than the power contacts 120, 130.

As shown in FIG. 1A, it is possible that the isolation part 140 extends to the external bus bar 1000 such that the bus bar 1000 is arranged on both sides of the isolation part 140.

The isolation part 140 may comprise or consist of an electrically isolating layer arranged between the power contacts 120, 130. The isolation part 140 may comprise or consist of any suitable electrically isolating material. For example, the isolation part 140 may comprise or consist of a polymer, a ceramic or an organic or inorganic coating.

According to an example, the circumference of the isolation part 140 as viewed from above the broadest surfaces of the power contacts 120, 130 is in vertical alignment or at least partially in vertical alignment with the circumference of the power contacts 120, 130. However, it is for example also possible that the isolation part 140 extends beyond the circumference of the power contacts 120, 130.

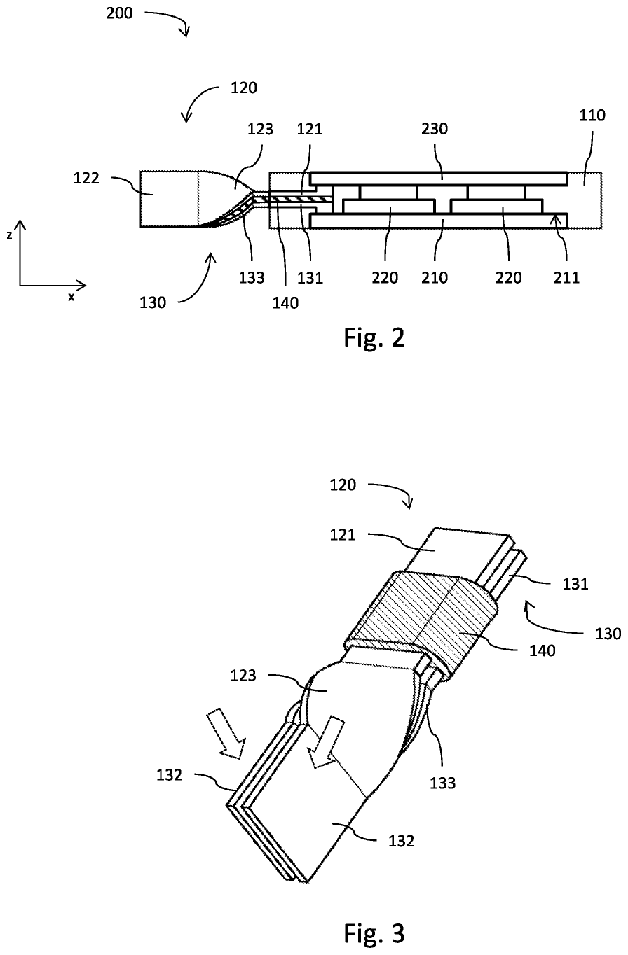

FIG. 2 shows a side view of a further power semiconductor module 200 which may be similar or identical to the power semiconductor module 100, except for the differences described in the following. FIG. 2 in particular shows the interior of the encapsulation 110 according to a specific example.

The power semiconductor module 200 comprises a power electronic substrate 210, wherein a plurality of power semiconductor dies 220 is arranged on and electrically coupled to a first side 211 of the power electronic substrate 210.

At least the second power contact 130 may be mechanically and electrically coupled to the power electronic substrate 210, for example to the first side 211 of the power electronic substrate. The first power contact 120 may for example be coupled to a connector part 230, wherein the connector part 230 is coupled to the power semiconductor dies 220. The first portion 131 of the power contacts 120, 130 may be parallel to the first side 211 of the power electronic substrate 210.

As shown in FIG. 2, the isolation part 140 may be arranged along the whole length of the power contacts 120, 130. However, it is also possible that the isolation part 140 is not arranged along the whole length. For example, the isolation part 140 may be replaced by material of the encapsulation 110 between the parts of the power contacts 120, 130 that are internal to the encapsulation 110.

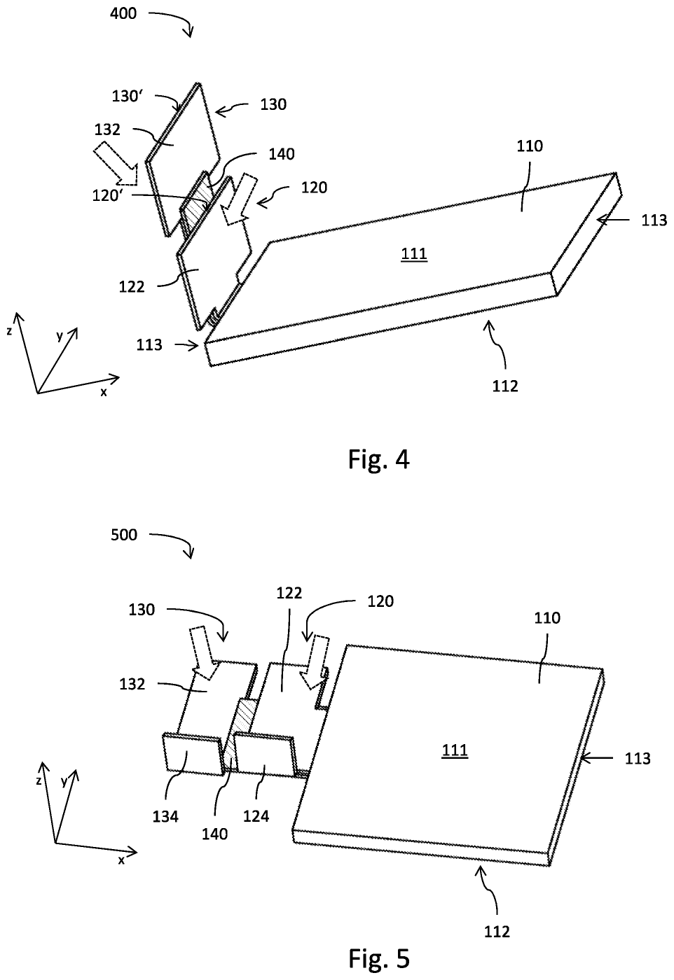

According to an example, the power contacts 120, 130 may have an L-shape or a T-shape as described with respect to FIGS. 4 and 5 further below.

Having the power contacts 120, 130 twist from the first plane into the second plane may for example simplify the process of mounting the power semiconductor module 100 or 200 to an external appliance. For example, the power contacts 120, 130 may be configured to be mounted to a bus bar. By having the second portions 122, 132 of the power contacts 120, 130 arranged in the second plane, it may be possible to weld (in particular to laser weld) both of the power contacts 120, 130 from the same direction, e. g. from above the first side 111 of the encapsulation (this is indicated by the pair of dashed arrows in FIG. 3). If on the other hand the second portions 122, 132 were arranged in the first plane like the first portions 121, 131 are, it would be necessary to weld the first power contact 120 from above the power semiconductor module 100 or 200 and to weld the second power contact 130 from below the power semiconductor module 100 or 200. This however would necessitate rotating the whole appliance to which the power semiconductor module 100 is being mounted or to provide two welding apparatuses, one for welding from above and one for welding from below. Both of these scenarios may be impractical or even impossible and/or may increase complexity and cost of the mounting process.

FIG. 3 shows a perspective view of the power contacts 120, 130 according to an example in greater detail.

As shown in FIG. 3, the isolation part 140 is not only arranged between the power contacts 120, 130 but also at least partially covers the outward-facing surfaces of the power contacts 120, 130. Such a configuration of the isolation part 140 may for example be used to seal a molding cavity at the power contacts 120, 130 (wherein the molding cavity may be used to fabricate the encapsulation 110).

In the example shown in FIG. 3, the isolation part 140 only extends partially along the power contacts 120, 130. As mentioned previously, the isolation part 140 (in particular, the portion of the isolation part 140 arranged between the power contacts 120, 130) may of course also extend along the whole length of the power contacts 120, 130.

According to an example, the portion of the isolation part 140 arranged between the power contacts 120, 130 and the portion of the isolation part 140 covering the outward-facing surfaces of the power contacts 120, 130 are a monobloc piece. According to another example, these portions are two distinct pieces and may for example comprise or consist of different materials.

FIG. 4 shows a perspective view of a further power semiconductor module 400 which may be similar or identical to the power semiconductor module 100 or 200, except for the differences described in the following.

In particular, in the power semiconductor module 400 the first and second power contacts 120, 130 are not necessarily twisted from a first plane into a second plane. The first and second power contacts 120, 130 of the power semiconductor module 400 however have different lengths such that a distal end 130′ of the second power contact 130 is at a greater distance from the respective lateral side 113 of the encapsulation 110 than a distal end 120′ of the first power contact 120.

Furthermore, the power contacts 120, 130 of the power semiconductor module 400 have a flat shape and the power contacts 120, 130 are stacked such that broadest surfaces of the power contacts 120, 130 at least partially overlap between the respective lateral side 113 of the encapsulation 110 and the distal end 120′ of the first power contact 120.

According to example, the outlines or an circumferences of the power contacts 120, 130 (and also the outline of the isolation part 140) completely overlap between the respective lateral side 113 and the distal end 120′ of the first power contact 120 (at least along one leg of L-shaped or T-shaped power contacts 120, 130).

Viewed from above the broadest surfaces, the power contacts 120, 130 have a T-shape or an L-shape (in the example depicted in FIG. 4, the power contacts 120, 130 have a T-shape). Both power contacts 120, 130 may essentially have the same shape or different shapes. For example, both power contacts 120, 130 may have an L-shape or a T-shape or one of the power contacts 120, 130 may have a T-shape and the other one may e.g. have an L-shape or any other suitable shape.

As shown in FIG. 4, the power contacts 120, 130 may be configured such that the second portions 122, 132 of the power contacts 120, 130 are at least partially spaced apart from each other. In other words, at least a part of the second portions 122, 132 does not necessarily overlap (in the example shown in FIG. 4, first legs of the T-shaped power contacts 120, 130 partially overlap and second legs of the T-shaped power contacts 120, 130 do not overlap). This may for example be done in order to provide sufficient space for laser welding external applications like e.g. a bus bar to the second portions 122, 132. Another way to provide sufficient space for laser welding such external applications to the second portions 122, 132 may e.g. be to increase the size of the gap between the power contacts 120, 130.

According to the example shown in FIG. 4, the isolation part 140 is arranged at least partially along the respective first ones of the legs of the T-shaped power contacts 120, 130 but not along the respective second ones of the legs.

According to the example shown in FIG. 4, the first portions 121, 131 of the power contacts 120, 130 are parallel to a first plane (the xy-plane in FIG. 4) and the second portions 122, 132 of the power contacts 120, 130 are bent with respect to the first portions 121, 131 such that the second portions 122, 132 are parallel to a second plane (the yz-plane in FIG. 4), wherein the second plane is arranged at a non-zero angle with respect to the first plane.

In the example shown in FIG. 4, the non-zero angle is an angle of 90°. However, the non-zero angle may be any suitable angle and may also for example be about 10°, 20°, 30°, 40°, 50°, 60°, 70°, 80°, 100°, 110°, 120°, 130°, 140°, 150°, 160°, 170°, or 180°. The non-zero angle may also be within a range of ±5° of any of the aforementioned values.

FIG. 5 shows a perspective view of a further power semiconductor module 500 which may be similar or identical to the power semiconductor module 400, except for the differences described in the following.

In particular, the power contacts 120, 130 of the power semiconductor module 500 each comprise a third portion 124, 134, wherein the third portions 124, 134 are bent with respect to the second portions 122, 132 and possibly also with respect to the first portions 121, 131. It should be noted that if the third portions 124, 134 were omitted, than the power contacts 120, 130 would have an L-shape instead of a T-shape.

In the example shown in FIG. 5, the first and second portions 121, 131 and 122, 132 are arranged in the same plane (the xy-plane). However, it is also possible that only the first portions 121, 131 are arranged in the xy-plane and the second portions 122, 132 are arranged in a different second plane, e.g. the yz-plane (compare FIG. 4). In that case, the third portions 124, 134 may be bent out of the second plane such that the third portions 124, 134 are parallel to a third plane, the third plane being different from the first and second planes. The third plane may for example be the xz-plane in FIG. 5. An angle between the second and third planes may for example be about 10°, 20°, 30°, 40°, 50°, 60°, 70°, 80°, 90°, 100°, 110°, 120°, 130°, 140°, 150°, 160°, 170°, or 180° or within a range of ±5° of any of these values.

By providing the partially non-overlapping T-shaped or L-shaped power contacts 120, 130 and alternatively or additionally by bending the power contacts 120, 130 from the first plane into the second plane, it may be possible to weld (in particular, to laser weld) both of the power contacts 120, 130 from the same direction (e.g. from above the power semiconductor module 400 or 500). This is indicated by the pair of dashed arrows in FIGS. 4 and 5. The T-shape may in particular allow welding a second connection, e.g. a connection to a battery, to the power contacts 120, 130, thereby optimizing the electrical resistance of the system.

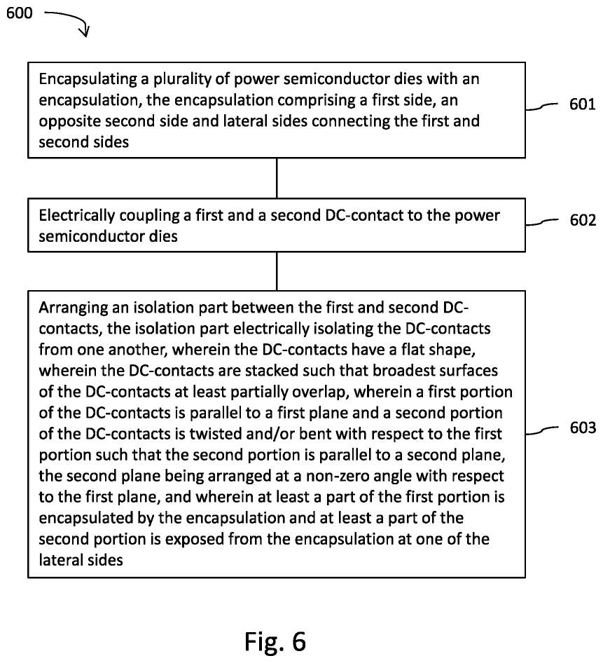

FIG. 6 is a flow chart of a method 600 for fabricating a power semiconductor module. The method 600 may for example be used to fabricate the power semiconductor modules 100 and 200.

The method 600 comprises at 601 a process of encapsulating a plurality of power semiconductor dies with an encapsulation, the encapsulation comprising a first side, an opposite second side and lateral sides connecting the first and second sides, at 602 a process of electrically coupling a first and a second power contact to the power semiconductor dies, and at 603 a process of arranging an isolation part between the first and second power contacts, the isolation part electrically isolating the power contacts from one another, wherein the power contacts have a flat shape, wherein the power contacts are stacked such that broadest surfaces of the power contacts at least partially overlap, wherein a first portion of the power contacts is parallel to a first plane and a second portion of the power contacts is twisted and/or bent with respect to the first portion such that the second portion is parallel to a second plane, the second plane being arranged at a non-zero angle with respect to the first plane, and wherein at least a part of the first portion is encapsulated by the encapsulation and at least a part of the second portion is exposed from the encapsulation at one of the lateral sides.

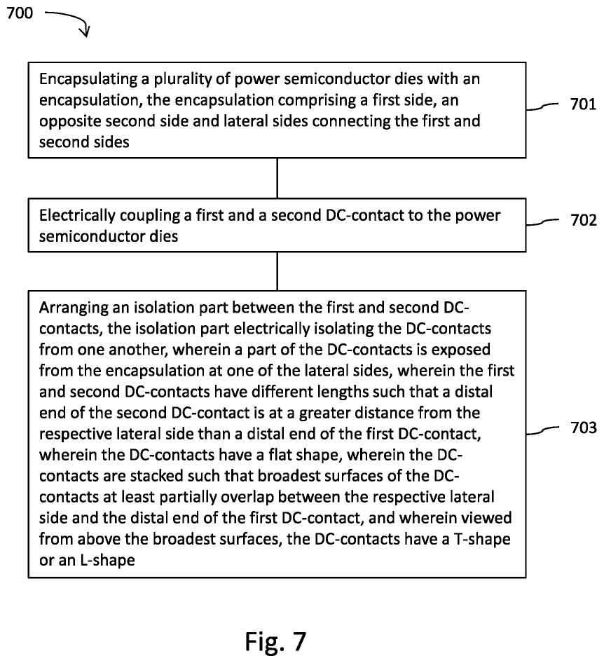

FIG. 7 is a flow chart of a method 700 for fabricating a power semiconductor module. The method 700 may for example be used to fabricate the power semiconductor modules 400 and 500.

The method 700 comprises at 701 a process of encapsulating a plurality of power semiconductor dies with an encapsulation, the encapsulation comprising a first side, an opposite second side and lateral sides connecting the first and second sides, at 702 a process of electrically coupling a first and a second power contact to the power semiconductor dies, and at 703 a process of arranging an isolation part between the first and second power contacts, the isolation part electrically isolating the power contacts from one another, wherein a part of the power contacts is exposed from the encapsulation at one of the lateral sides, wherein the first and second power contacts have different lengths such that a distal end of the second power contact is at a greater distance from the respective lateral side than a distal end of the first power contact, wherein the power contacts have a flat shape, wherein the power contacts are stacked such that broadest surfaces of the power contacts at least partially overlap between the respective lateral side and the distal end of the first power contact, and wherein viewed from above the broadest surfaces, the power contacts have a T-shape or an L-shape.

In the following, the power semiconductor module and the method for fabricating a power semiconductor module are further explained using specific examples.

Example 1 is a power semiconductor module, comprising: an encapsulation encapsulating a plurality of power semiconductor dies, the encapsulation comprising a first side, an opposite second side and lateral sides connecting the first and second sides, a first and a second power contact electrically coupled to the power semiconductor dies, and an isolation part arranged between the first and second power contacts and electrically isolating the power contacts from one another, wherein the power contacts have a flat shape, wherein the power contacts are stacked such that broadest surfaces of the power contacts at least partially overlap, wherein a first portion of the power contacts is parallel to a first plane and a second portion of the power contacts is twisted and/or bent with respect to the first portion such that the second portion is parallel to a second plane, the second plane being arranged at a non-zero angle with respect to the first plane, and wherein at least a part of the first portion is encapsulated by the encapsulation and at least a part of the second portion is exposed from the encapsulation at one of the lateral sides.

Example 2 is the power semiconductor module of example 1, wherein the non-zero angle is in the range of 85° to 95°, in particular 90°.

Example 3 is the power semiconductor module of example 1 or 2, wherein the power semiconductor dies are arranged on a first side of a power electronic substrate, and wherein the first plane is parallel to the first side of the power electronic substrate.

Example 4 is the power semiconductor module of one of the preceding examples, wherein viewed from above the broadest surfaces, the second portion has an L-shape or a T-shape.

Example 5 is the power semiconductor module of one of the preceding examples, wherein viewed from above the broadest surfaces, the first and second power contacts have overlapping outlines.

Example 6 is the power semiconductor module of one of the preceding examples, wherein the power contacts comprise one or more bend portions arranged between the first and second portions, wherein the power contacts bend from the first plane towards the second plane along the one or more bend portions.

Example 7 is the power semiconductor module of one of the preceding examples, wherein the power contacts comprise a twist portion arranged between the first and second portions, wherein the power contacts twist from the first plane towards the second plane along the twist portion, and wherein the twist portion and the second are exposed portion from the encapsulation.

Example 8 is a power semiconductor module, comprising: an encapsulation encapsulating a plurality of power semiconductor dies, the encapsulation comprising a first side, an opposite second side and lateral sides connecting the first and second sides, a first and a second power contact electrically coupled to the power semiconductor dies, and an isolation part arranged between the first and second power contacts and electrically isolating the power contacts from one another, wherein a part of the power contacts is exposed from the encapsulation at one of the lateral sides, wherein the first and second power contacts have different lengths such that a distal end of the second power contact is at a greater distance from the respective lateral side than a distal end of the first power contact, wherein the power contacts have a flat shape, wherein the power contacts are stacked such that broadest surfaces of the power contacts at least partially overlap between the respective lateral side and the distal end of the first power contact, and wherein viewed from above the broadest surfaces, the power contacts have a T-shape or an L-shape.

Example 9 is the power semiconductor module of example 8, wherein viewed from above the broadest surfaces, the outlines of the power contacts completely overlap between the respective lateral side and the distal end of the first power contact.

Example 10 is the power semiconductor module of example 8 or 9, wherein respective first ones of the legs of the T-shape or L-shape of the power contacts at least partially overlap and respective second ones of the legs of the T-shape or L-shape do not overlap.

Example 11 is the power semiconductor module of example 10, wherein the isolation part is arranged at least partially along the respective first ones of the legs but not along the respective second ones of the legs.

Example 12 is the power semiconductor module of one of examples 8 to 11, wherein a first portion of the power contacts is parallel to a first plane and a second portion of the power contacts is bent with respect to the first portion such that the second portion is parallel to a second plane, the second plane being arranged at a non-zero angle with respect to the first plane.

Example 13 is the power semiconductor module of example 8, wherein the non-zero angle is in the range of 85° to 95°, in particular 90°.

Example 14 is the power semiconductor module of example 12 or 13, wherein the power semiconductor dies are arranged on a first side of a power electronic substrate, and wherein the first plane is parallel to the first side of the power electronic substrate.

Example 15 is the power semiconductor module of one of examples 12 to 14, wherein at least a part of the first portion is encapsulated by the encapsulation and the second portion is completely exposed from the encapsulation.

Example 16 is the power semiconductor module of one of examples 12 to 15, further comprising: a third portion of the power contacts, wherein the third portion is bent with respect to the first and second portions such that the third portion is parallel to a third plane, the third plane being different from the first and second planes.

Example 17 is a method for fabricating a power semiconductor module, the method comprising: encapsulating a plurality of power semiconductor dies with an encapsulation, the encapsulation comprising a first side, an opposite second side and lateral sides connecting the first and second sides, electrically coupling a first and a second power contact to the power semiconductor dies, and arranging an isolation part between the first and second power contacts, the isolation part electrically isolating the power contacts from one another, wherein the power contacts have a flat shape, wherein the power contacts are stacked such that broadest surfaces of the power contacts at least partially overlap, wherein a first portion of the power contacts is parallel to a first plane and a second portion of the power contacts is twisted and/or bent with respect to the first portion such that the second portion is parallel to a second plane, the second plane being arranged at a non-zero angle with respect to the first plane, and wherein at least a part of the first portion is encapsulated by the encapsulation and at least a part of the second portion is exposed from the encapsulation at one of the lateral sides.

Example 18 is the method of example 17, wherein viewed from above the broadest surfaces, the first and second power contacts have overlapping outlines.

Example 19 is a method for fabricating a power semiconductor module, the method comprising: encapsulating a plurality of power semiconductor dies with an encapsulation, the encapsulation comprising a first side, an opposite second side and lateral sides connecting the first and second sides, electrically coupling a first and a second power contact to the power semiconductor dies, and arranging an isolation part between the first and second power contacts, the isolation part electrically isolating the power contacts from one another, wherein a part of the power contacts is exposed from the encapsulation at one of the lateral sides, wherein the first and second power contacts have different lengths such that a distal end of the second power contact is at a greater distance from the respective lateral side than a distal end of the first power contact, wherein the power contacts have a flat shape, wherein the power contacts are stacked such that broadest surfaces of the power contacts at least partially overlap between the respective lateral side and the distal end of the first power contact, and wherein viewed from above the broadest surfaces, the power contacts have a T-shape or an L-shape.

Example 20 is the method of claim 19, wherein respective first ones of the legs of the T-shape or L-shape of the power contacts at least partially overlap and respective second ones of the legs of the T-shape or L-shape do not overlap.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor module, comprising:
an encapsulation encapsulating a plurality of power semiconductor dies, the encapsulation comprising a first side, an opposite second side, and lateral sides connecting the first and the second sides;
a first power contact and a second power contact electrically coupled to the power semiconductor dies; and
an isolation part arranged between the first and the second power contacts and electrically isolating the first and the second power contacts from one another,
wherein the first and the second power contacts have a flat shape and are stacked such that broadest surfaces of the first and the second power contacts at least partially overlap,
wherein a first portion of the first and the second power contacts is parallel to a first plane and a second portion of the first and the second power contacts is twisted and/or bent with respect to the first portion such that the second portion is parallel to a second plane, the second plane being arranged at a non-zero angle with respect to the first plane,
wherein at least a part of the first portion is encapsulated by the encapsulation and at least a part of the second portion is exposed from the encapsulation at one of the lateral sides.

2. The power semiconductor module of claim 1, wherein the non-zero angle is in a range of 85° to 95°.

3. The power semiconductor module of claim 1, wherein the power semiconductor dies are arranged on a first side of a power electronic substrate, and wherein the first plane is parallel to the first side of the power electronic substrate.

4. The power semiconductor module of claim 1, wherein when viewed from above the broadest surfaces, the second portion has an L-shape or a T-shape.

5. The power semiconductor module of claim 1, wherein when viewed from above the broadest surfaces, the first and the second power contacts have overlapping outlines.

6. The power semiconductor module of claim 1, wherein the first and the second power contacts comprise one or more bend portions arranged between the first and the second portions, and wherein the first and the second power contacts bend from the first plane towards the second plane along the one or more bend portions.

7. The power semiconductor module of claim 1, wherein the first and the second power contacts comprise a twist portion arranged between the first and the second portions, wherein the first and the second power contacts twist from the first plane towards the second plane along the twist portion, and wherein the twist portion and the second portion are exposed from the encapsulation.

8. A power semiconductor module, comprising:
an encapsulation encapsulating a plurality of power semiconductor dies, the encapsulation comprising a first side, an opposite second side, and lateral sides connecting the first and the second sides;
a first power contact and a second power contact electrically coupled to the power semiconductor dies; and
an isolation part arranged between the first and the second power contacts and electrically isolating the first and the second power contacts from one another,
wherein a part of the first and the second power contacts is exposed from the encapsulation at one of the lateral sides,
wherein the first and the second power contacts have different lengths such that a distal end of the second power contact is at a greater distance from the respective lateral side than a distal end of the first power contact,
wherein the first and the second power contacts have a flat shape,
wherein the first and the second power contacts are stacked such that broadest surfaces of the first and the second power contacts at least partially overlap between the respective lateral side and the distal end of the first power contact,
wherein when viewed from above the broadest surfaces, the first and the second power contacts have a T-shape or an L-shape.

9. The power semiconductor module of claim 8, wherein when viewed from above the broadest surfaces, the outlines of the first and the second power contacts completely overlap between the respective lateral side and the distal end of the first power contact.

10. The power semiconductor module of claim 8, wherein respective first legs of the T-shape or L-shape of the first and the second power contacts at least partially overlap and respective second legs of the T-shape or L-shape do not overlap.

11. The power semiconductor module of claim 10, wherein the isolation part is arranged at least partially along the respective first legs but not along the respective second legs.

12. The power semiconductor module of claim 8, wherein a first portion of the first and the second power contacts is parallel to a first plane and a second portion of the first and the second power contacts is bent with respect to the first portion such that the second portion is parallel to a second plane, the second plane being arranged at a non-zero angle with respect to the first plane.

13. The power semiconductor module of claim 12, wherein the non-zero angle is in a range of 85° to 95°.

14. The power semiconductor module of claim 12, wherein the power semiconductor dies are arranged on a first side of a power electronic substrate, and wherein the first plane is parallel to the first side of the power electronic substrate.

15. The power semiconductor module of claim 12, wherein at least a part of the first portion is encapsulated by the encapsulation and the second portion is completely exposed from the encapsulation.

16. The power semiconductor module of claim 12, wherein a third portion of the first and the second power contacts is bent with respect to the first and second portions such that the third portion is parallel to a third plane, the third plane being different from the first and second planes.

17. A method for fabricating a power semiconductor module, the method comprising:
encapsulating a plurality of power semiconductor dies with an encapsulation, the encapsulation comprising a first side, an opposite second side, and lateral sides connecting the first and second sides;
electrically coupling a first power contact and a second power contact to the power semiconductor dies; and
arranging an isolation part between the first and the second power contacts, the isolation part electrically isolating the first and the second power contacts from one another,
wherein the first and the second power contacts have a flat shape,
wherein the first and the second power contacts are stacked such that broadest surfaces of the first and the second power contacts at least partially overlap, wherein a first portion of the first and the second power contacts is parallel to a first plane and a second portion of the first and the second power contacts is twisted and/or bent with respect to the first portion such that the second portion is parallel to a second plane, the second plane being arranged at a non-zero angle with respect to the first plane,
wherein at least a part of the first portion is encapsulated by the encapsulation and at least a part of the second portion is exposed from the encapsulation at one of the lateral sides.

18. The method of claim 17, wherein when viewed from above the broadest surfaces, the first and the second power contacts have overlapping outlines.

19. A method for fabricating a power semiconductor module, the method comprising:
encapsulating a plurality of power semiconductor dies with an encapsulation, the encapsulation comprising a first side, an opposite second side, and lateral sides connecting the first and second sides;
electrically coupling a first power contact and a second power contact to the power semiconductor dies; and
arranging an isolation part between the first and the second power contacts, the isolation part electrically isolating the first and the second power contacts from one another,
wherein a part of the first and the second power contacts is exposed from the encapsulation at one of the lateral sides,
wherein the first and the second power contacts have different lengths such that a distal end of the second power contact is at a greater distance from the respective lateral side than a distal end of the first power contact,
wherein the first and the second power contacts have a flat shape,
wherein the first and the second power contacts are stacked such that broadest surfaces of the first and the second power contacts at least partially overlap between the respective lateral side and the distal end of the first power contact,
wherein when viewed from above the broadest surfaces, the first and the second power contacts have a T-shape or an L-shape.

20. The method of claim 19, wherein respective first legs of the T-shape or L-shape of the first and the second power contacts at least partially overlap and respective second legs of the T-shape or L-shape do not overlap.
